(19) United States
(12) Patent Application Publication
(10) Pub. No.: US 2026/0372081 A1
(43) Pub. Date: Nov. 19, 2026

(54) INTEGRATED POWER ELECTRONIC COMPONENT, MANUFACTURING METHOD, POWER UNIT, AND POWER SUPPLY ARCHITECTURE

(71) Applicant: MetaPWR Electronics Co., Ltd., Shanghai (CN)

(72) Inventors: Mingzhun ZHANG, Shanghai (CN); Xiaoni Xin, Shanghai (CN); Jianhong ZENG, Shanghai (CN)

(73) Assignee: MetaPWR Electronics Co., Ltd., Shanghai (CN)

(21) Appl. No.: 19/681,100

(22) Filed: May 19, 2026

(30) Foreign Application Priority Data
May 19, 2025 (CN) 202510641958.7

(51) Int. Cl. H10W 40/20; H05K 1/181; H10W 70/40; H10W 74/10

(52) U.S. Cl. CPC H10W 40/235; H05K 1/181; H10W 70/421; H10W 74/111; H05K 2201/1003

(57) ABSTRACT

An integrated power electronic component includes opposite top and bottom surfaces and four side surfaces extending between the top and bottom surfaces. A top heat dissipation portion is disposed on the top surface, a side heat dissipation portion is disposed on one of the side surfaces, and pins are disposed on the bottom surface. A distance between the top surface and the bottom surface defines a height of the integrated power electronic component. The integrated power electronic component further includes a length and a width, wherein the height of the integrated power electronic component is greater than the length or the width, such that the integrated power electronic component is configured to be vertically mounted. A power unit includes an inductor and the integrated power electronic component arranged in a horizontal arrangement.

### CROSS-REFERENCE TO RELATED APPLICATIONS

This disclosure claims the priority benefit of Chinese patent application no. 202510641958.7 filed on May 19, 2025. The entirety of the above-mentioned patent application is hereby incorporated by reference herein and made a part of this specification.

### BACKGROUND

In recent years, with the development of technologies in fields such as data centers, artificial intelligence, and supercomputers, increasingly powerful ASICs have been applied, such as CPUs, GPUs, TPUs, NPUs, ML processors, AI accelerators, network switches, and servers. These ASICs consume a large amount of current, for example, up to several thousand amperes, and impose increasingly higher requirements on the dynamic response of power supplies. Traditionally, voltage regulator modules (VRMs, Voltage Regulator Modules) are often used to supply power to such loads. With the advancement of semiconductor technology, the power supplied to ASICs has further increased, while the supply voltage required by ASICs has become increasingly lower. Therefore, the supply current of ASICs continues to increase. As the supply current of ASICs increases, the output power and output current of VRMs also increase. Improving the conversion efficiency of VRMs has become critical to increasing VRM power. On the other hand, as requirements for power density continue to increase, the size of voltage regulator modules is required to become increasingly smaller. Therefore, improving the power density of voltage regulator modules, improving conversion efficiency, and ensuring the reliability of voltage regulator modules are technical problems faced in this field.

### SUMMARY

In view of the above, one of the objectives of the disclosure is to an integrated power electronic component, comprising: an upper switch and a lower switch, wherein the upper switch and the lower switch are electrically connected in series; four side surfaces, and a top surface and a bottom surface opposite to each other, wherein the top surface is provided with a top heat dissipation portion, one of the side surfaces is provided with a side heat dissipation portion, and the bottom surface is provided with pins; a distance between the top surface and the bottom surface is a height of the integrated power electronic component, the top surface and/or the bottom surface of the integrated power electronic component is rectangular, with two adjacent sides of the rectangle respectively corresponding to a length direction and a width direction of the integrated power electronic component, and the height is greater than the length and/or the width.

Preferably, the integrated power electronic component further comprises a capacitor, the capacitor is arranged on a side surface of the integrated power electronic component, and the capacitor and the side heat dissipation portion are arranged opposite to each other.

Preferably, the pins arranged on the bottom surface comprise a first power pin, a second power pin, an SW pin, and a signal pin.

Preferably, on the bottom surface of the integrated power electronic component, the second power pin, the SW pin, the first power pin, and the signal pin are sequentially arranged along a same direction, or the SW pin, the second power pin, the first power pin, and the signal pin are sequentially arranged along the same direction.

Preferably, a signal pin is arranged on a side surface of the integrated power electronic component, and the signal pin arranged on the bottom surface and the signal pin arranged on the side surface are arranged adjacent to each other.

Preferably, the top heat dissipation portion is electrically connected with the SW pin or the second power pin, and the side heat dissipation portion is electrically connected with the SW pin or the second power pin.

Preferably, the integrated power electronic component comprises: a first lead frame and a second lead frame, each comprising a first portion, a second portion, and a third portion; a first switching die and a second switching die, both arranged between the first lead frame and the second lead frame; wherein a bottom surface of the first switching die and a bottom surface of the second switching die are electrically connected through the first lead frame and thermally connected with the first lead frame respectively , a top surface of the first switching die is electrically connected and thermally connected with the first portion of the second lead frame, and a top surface of the second switching die is electrically connected and thermally connected with the second portion of the second lead frame; wherein the integrated power electronic component further comprises a logic control die and wires.

Preferably, the wires comprise a first wire, a second wire, and a third wire; the first wire electrically connects the logic control die and the first switching die; the second wire electrically connects the logic control die and the second switching die; and the third wire electrically connects the logic control die with the third portion of the first lead frame and the third portion of the second lead frame.

Preferably, the logic control die is arranged on the second portion of the first lead frame.

Preferably, the integrated power electronic component further comprises a first molded body, and the first lead frame, the second lead frame, the first switching die, the second switching die, the logic control die, and the wires are located in the first molded body.

Preferably, the first molded body comprises a top surface and a bottom surface opposite to each other and four side surfaces located between the top surface and the bottom surface; the top surface and the bottom surface of the first molded body are both rectangular and each comprise a long side and a short side; two opposite side surfaces corresponding to two long sides of the top surface and the bottom surface are respectively provided with the side heat dissipation portion and the capacitor; and the top surface of the first molded body is provided with the top heat dissipation portion.

Preferably, the integrated power electronic component further comprises a second molded body, and the capacitor is located in the second molded body.

Preferably, the integrated power electronic component further comprises a substrate, a capacitor, and other passive components, and the first lead frame, the second lead frame, the first switching die, the second switching die, the logic control die, the wires, the capacitor, and the other passive components are embedded in the substrate.

Preferably, the first portion, the second portion, and the third portion of the first lead frame are electrically isolated from one another, and the first portion, the second portion, and the third portion of the second lead frame are electrically isolated from one another.

Preferably, the integrated power electronic component comprises: a substrate comprising a first surface and a second surface opposite to each other; an integrated die comprising a logic control portion and a power switching portion; a capacitor and other passive components; wherein the integrated die and the other passive components are arranged on the first surface of the substrate, and the capacitor is arranged on the second surface of the substrate; a third molded body configured to encapsulate the first surface of the substrate, the integrated die, and the other passive components; a fourth molded body configured to encapsulate the second surface of the substrate and the capacitor; and a first power pin, a second power pin, an SW pin, and a signal pin, all arranged on the bottom surface of the integrated power electronic component, wherein the bottom surface is perpendicular to the substrate.

Another objective of the disclosure is to provide a method for manufacturing the integrated power electronic component. The manufacturing method comprises: a preprocessing step, comprising silicon die preprocessing and lead frame preprocessing, wherein the silicon die preprocessing is performed to obtain the first switching die, the second switching die, and the logic control die that satisfy specifications, and the lead frame preprocessing is performed to preform the first lead frame and the second lead frame; a first step: arranging a conductive medium on a top surface of the first lead frame, and attaching the preprocessed first switching die, second switching die, and logic control die to the top surface of the first lead frame; continuing to arrange a conductive medium above the first switching die, the second switching die, and the logic control die, and attaching the second lead frame above the first switching die, the second switching die, and the logic control die; a second step: performing wire bonding respectively between the logic control die and the first switching die, the second switching die, the third portion of the first lead frame, and the third portion of the second lead frame; and a third step: molding and encapsulating the integrated power electronic component after completion of the wire bonding to form a first molded body; arranging at least two wiring layers on a surface of the first molded body to alternately lead an input positive terminal and an input negative terminal out to the surface of the first molded body; mounting a capacitor and other passive components on the surface of the first molded body, and molding the capacitor and the other passive components through secondary molding to form a second molded body; removing redundant structures at a periphery of the lead frames and non-functional portions of tie bars of the lead frames, and forming, by a plating process, a signal pin, a first power pin, a second power pin, and an SW pin on a bottom surface of the first molded body.

Preferably, the third step further comprises leading the second power pin and the SW pin inside the integrated power electronic component out to a top portion or a side surface of the integrated power electronic component to form a top heat dissipation portion and a side heat dissipation portion.

Another objective of the disclosure is to provide a method for manufacturing the integrated power electronic component, which comprises: a first step: mounting the integrated die and the other passive components on the first surface of the substrate, and mounting the capacitor on the second surface of the substrate; a second step: performing a double-sided molding process on the semi-finished integrated power electronic component having components mounted on both sides in the first step, thereby forming a third molded body and a fourth molded body; a third step: performing a plating process on bottom surfaces of the third molded body and the fourth molded body, and forming the first power pin, the second power pin, the SW pin, and the signal pin; forming the top heat dissipation portion by plating on top surfaces of the third molded body and the fourth molded body; and forming the side heat dissipation portion by plating on a side surface of the third molded body.

Preferably, the top heat dissipation portion is thermally connected with metal layer in the substrate, and the side heat dissipation portion is thermally connected with a surface of the integrated die.

Another objective of this disclosure is to provide a power unit, which comprises: an inductor comprising a magnetic core and a main winding, wherein the magnetic core comprises four side surfaces and a top surface and a bottom surface opposite to each other; and the integrated power electronic component; the inductor and the integrated power electronic component are horizontally arranged; pins on the bottom surface of the integrated power electronic component are electrically connected with the inductor through a circuit board; the integrated power electronic component and the inductor are arranged on a top surface of the circuit board; and a side surface of the integrated power electronic component opposite to the side heat dissipation portion is arranged adjacent to the inductor.

Preferably, the number of the integrated power electronic components is two, the two integrated power electronic components are respectively arranged adjacent to two opposite sides of the inductor, the inductor comprises two main windings, and one end of each main winding is electrically connected with one integrated power electronic component.

Preferably, the top surface of the inductor and the top surface of the integrated power electronic component are substantially coplanar.

Preferably, the number of the integrated power electronic components is four, and the four integrated power electronic components are arranged adjacent to one side surface of the magnetic core and sequentially arranged along the side surface; the inductor comprises four main windings, one end of each main winding is electrically connected with a respective integrated power electronic component, and the four main windings are sequentially arranged along the same direction.

Preferably, the number of the integrated power electronic components is four, and the four integrated power electronic components are respectively arranged adjacent to one side surface of the magnetic core; the inductor comprises four main windings, one end of each main winding is electrically connected with a respective integrated power electronic component, and two ends of each main winding are respectively located on two adjacent side surfaces of the magnetic core.

Preferably, output capacitors are arranged on the circuit board, and the output capacitors are arranged adjacent to side surfaces of two adjacent integrated power electronic components and four corners of the magnetic core.

Preferably, the four integrated power electronic components are arranged around a periphery of the inductor in an end-to-end manner.

Preferably, the number of the integrated power electronic components is four, and the four integrated power electronic components are arranged in two groups respectively on two opposite side surfaces of the magnetic core; the inductor comprises four main windings, one end of each main winding is electrically connected with a respective integrated power electronic component, and the four main windings are sequentially arranged in the magnetic core along a same direction.

Preferably, the inductor further comprises an auxiliary winding; the magnetic core comprises a magnetic core window, and the main winding and the auxiliary winding pass through the same magnetic core window; and the main winding and the auxiliary winding are arranged in parallel or are vertically stacked.

Preferably, a groove is provided in the bottom surface of the magnetic core, and an output capacitor is arranged in the groove.

Another objective of the disclosure is to provide a power supply architecture, comprising a semiconductor chip and the power unit, the power unit supplies power to the semiconductor chip.

Preferably, the power unit and the semiconductor chip are horizontally arranged and are both arranged on the top surface of the circuit board.

Preferably, the power supply architecture further comprises a system board, and the power unit arranged on the circuit board and the semiconductor chip are horizontally arranged and are both arranged on a top surface of the system board.

Preferably, the number of the power units is M*N, where M and N are both natural numbers greater than 1; the M*N power units are electrically connected in parallel; the semiconductor chip is arranged adjacent to a bottom surface of the circuit board; and the M*N power units are arranged adjacent to the top surface of the circuit board.

Preferably, the power supply architecture further comprises a system board, the semiconductor chip is arranged on a bottom surface of the system board, and the circuit board is arranged on a top surface of the system board.

Compared with the prior art, the disclosure has the following beneficial effects:
(1) The present disclosure provides an integrated power electronic component. By improving the internal structure of the integrated power electronic component, providing pins on the bottom surface of the integrated power electronic component, and respectively providing a top heat dissipation portion and a side heat dissipation portion on the top surface and a side surface thereof, the heat dissipation capability and performance of the device are enhanced.
(2) The present disclosure further provides a structure of a power unit, in which the integrated power electronic component is arranged on a side of an inductor to form a power unit having a horizontal structure. The power unit having the horizontal structure can eliminate electrical connectors used in a power unit having a vertical structure, thereby simplifying the structure and manufacturing process of the power unit and improving the reliability of the power unit. In addition, the space utilization and power density of the power unit having the horizontal structure are improved.

### DESCRIPTION OF DRAWINGS

FIGS. 1A-1F show power modules in the prior art.

FIGS. 2A-2C show an embodiment of a power unit according to the present disclosure.

FIGS. 2D-1-2D-7 show an integrated power electronic component and a manufacturing process according to the present disclosure.

FIGS. 2E-2F-3 show another embodiment of the power unit according to the present disclosure.

FIGS. 2G-2K show embodiments of an inductor.

FIGS. 3A-3K show application examples of the power unit.

FIGS. 4A-4D show embodiments of a power supply architecture for vertical power supply.

FIGS. 5A-5F show embodiments of a power supply architecture for horizontal power supply.

### DETAILED DESCRIPTION

One of the core aspects of the present disclosure is to provide an integrated power electronic component. By improving the internal structure of the integrated power electronic component, providing pins on the bottom surface of the integrated power electronic component, and respectively providing a top heat dissipation portion and a side heat dissipation portion on its top surface and side surface, the heat dissipation capability and performance of the device are enhanced. In addition, the integrated power electronic component is arranged on a side of an inductor to form a power unit having a horizontal structure. The power unit having the horizontal structure can eliminate the electrical connectors used in a power unit having a vertical structure, thereby simplifying the structure and manufacturing process of the power unit and improving the reliability of the power unit. Furthermore, the space utilization and power density of the power unit having the horizontal structure are improved. The present disclosure also illustrates applications of the power unit in horizontal power supply and vertical power supply scenarios.

The technical solutions in the embodiments of the present disclosure will be clearly and completely described below with reference to the accompanying drawings in the embodiments of the present disclosure. It is apparent that the described embodiments are only some, rather than all, of the embodiments of the present disclosure. Based on the embodiments of the present disclosure, all other embodiments obtained by a person of ordinary skill in the art without creative effort shall fall within the protection scope of the present disclosure.

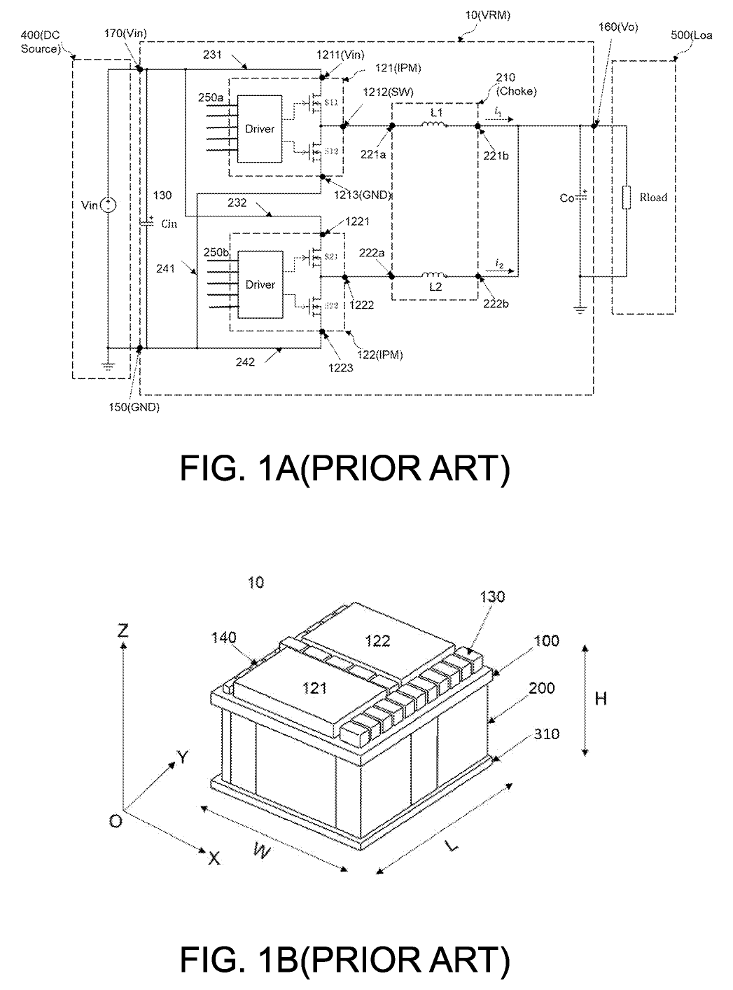

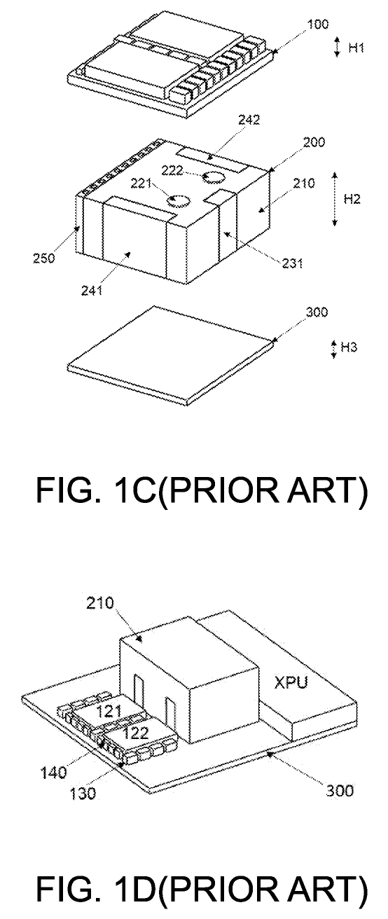

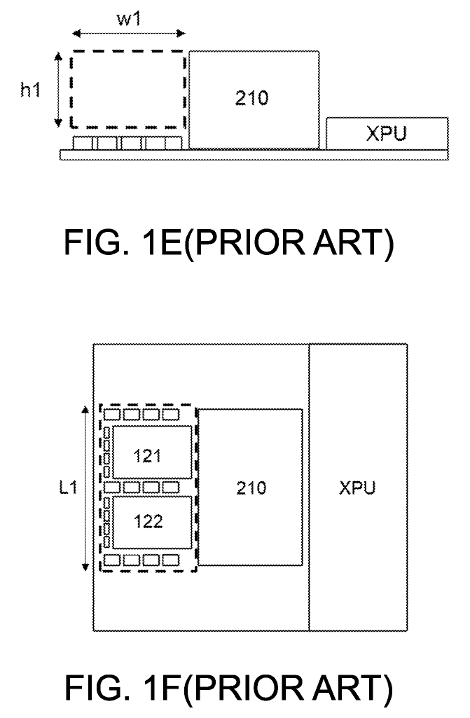

FIG. 1A is an equivalent circuit schematic diagram of a two-phase BUCK topology circuit. As shown in FIG. 1A, the two-phase BUCK circuit includes power semiconductor components 121 and 122, such as an IPM (Intelligent Power Module), an SPS (Smart Power Stage), or another power semiconductor component having a half-bridge structure, and a two-phase inductor 210. Each power semiconductor component includes an upper switch and a lower switch that are electrically connected in series. The drain electrode of the upper switch is electrically connected with an input positive terminal VIN+, the source electrode of the lower switch is electrically connected with an input negative terminal GND, and the source electrode of the upper switch is electrically connected with the drain electrode of the lower switch. In this embodiment, because the input negative terminal and the output negative terminal are short-circuited, the input negative terminal and the output negative terminal are hereinafter collectively referred to as the ground terminal GND. In each power semiconductor component, the source electrode of the upper switch and the drain electrode of the lower switch are electrically connected together and serve as the SW terminal of the power semiconductor component, which is electrically connected with the input terminal of an output filter inductor Ln. The output terminal of the output filter inductor Ln is electrically connected with a load to supply energy to the load, where n is an integer greater than or equal to 1. An input filter capacitor Cin is arranged between the input positive terminal VIN+ and the ground terminal GND to absorb high-frequency pulse current generated during switching of the switching transistors, reduce voltage spikes caused by parasitic inductance of the line, and thereby reduce the voltage fluctuation amplitude at the input terminal, effectively ensuring stable operation of the BUCK circuit. An output filter capacitor Co is arranged between the output terminal of the output filter inductor, that is, the output positive terminal, and the ground terminal GND to reduce voltage spikes caused by sudden changes in the inductor current and reduce voltage overshoot during dynamic processes, thereby improving the dynamic performance of the output voltage. FIG. 1A merely takes an equivalent circuit diagram of a two-phase BUCK circuit as an example. By increasing the number of power semiconductor components connected in parallel and the number of phases of the inductor, the circuit can be easily extended to a multi-phase BUCK circuit. The present disclosure uses a two-phase VRM module and a four-phase VRM module as examples to describe the technical features of the present disclosure, but the technical solutions of the present disclosure are applicable to a BUCK circuit having any number of phases.

FIG. 1B shows a high-power-density two-phase voltage regulator module (VRM) in the prior art, and FIG. 1C is an exploded structural view of FIG. 1B. As shown in FIGS. 1B and 1C, the VRM module includes a top assembly 100, a middle assembly 200 and a bottom assembly. The VRM module supply power to an external component through the bottom assembly. In another implementation, the VRM module don’t comprise the bottom assembly 310. The VRM module is directly electrically connected with the external component, such as a load motherboard or another circuit board, through the middle assembly. To reduce the upward thermal resistance of the VRM module, the power semiconductor components 121 and 122 are arranged on the top assembly. The top assembly is further provided with input filter capacitors 130 and passive components 140 of a driver circuit. The height H1 of the top assembly 100 accounts for approximately 30% of the overall height H of the VRM module. The middle assembly 200 includes a magnetic core 210, windings 221 and 222, a first power electrical connector 231, second power electrical connectors 241 and 242, and a signal electrical connector 250. The height H2 of the middle assembly accounts for approximately 60% of the overall height H of the VRM module, and the height H3 of the bottom assembly 310 accounts for approximately 10% of the overall height of the VRM module. Generally, the length of the VRM module, that is, the long-side length of the horizontal cross section of the VRM module, is twice the height of the VRM module. Therefore, the ratio of the length to the height of the inductor magnetic core in the middle assembly is greater than 3. For the inductor, this ratio is excessively large and is not conducive to improving inductor performance. Moreover, because the power semiconductor components 121 and 122 are horizontally spread on the substrate of the top assembly and occupy most of the area of the top substrate, the number of input capacitors on the top substrate is limited. The limited number of input capacitors is not conducive to improving the filtering effect of the input capacitors. The voltage spikes caused by parasitic inductance of the line are large, and therefore the voltage fluctuation amplitude at the input terminal is large. In addition, the VRM module adopts a three-layer stacked structure in the vertical direction, which requires multiple reflow soldering processes, has a complicated manufacturing process and high manufacturing difficulty, and makes it difficult to ensure product reliability.

FIG. 1D shows a two-phase BUCK power supply method in the prior art, which adopts a conventional discrete power supply solution. The power semiconductor components 121 and 122, the input filter capacitors 130, the passive components 140 of the driver circuit, the inductor 210, and the load are all arranged on a substrate 300. FIGS. 1E and 1F are respectively a side view and a top view of FIG. 1D. The space L1*W1*H1 above the power semiconductor components is not fully utilized, which is not conducive to improving the power density of the power supply.

Therefore, the prior art faces the following problems:
1. A power supply using a discrete solution has low power density.
2. In the VRM module solution, the ratio of the length to the height of the inductor is large, which is not conducive to improving inductor performance.
3. The power semiconductor components occupy a large area in the X direction and the Y direction, resulting in a small number of input capacitors, which is not conducive to reducing voltage spikes and the oscillation amplitude of the input voltage.
4. When the power semiconductor components adopt a horizontally spread structure, the current density and power density of the VRM module are difficult to further improve due to the limitation on the width-to-thickness ratio of the inductor.
5. The three-layer stacked structure results in high manufacturing difficulty, many reflow soldering processes, at least four times, and severe challenges to reliability.

To solve the above problems faced by the prior art, the present disclosure proposes a horizontal structure solution.

### Embodiment 1

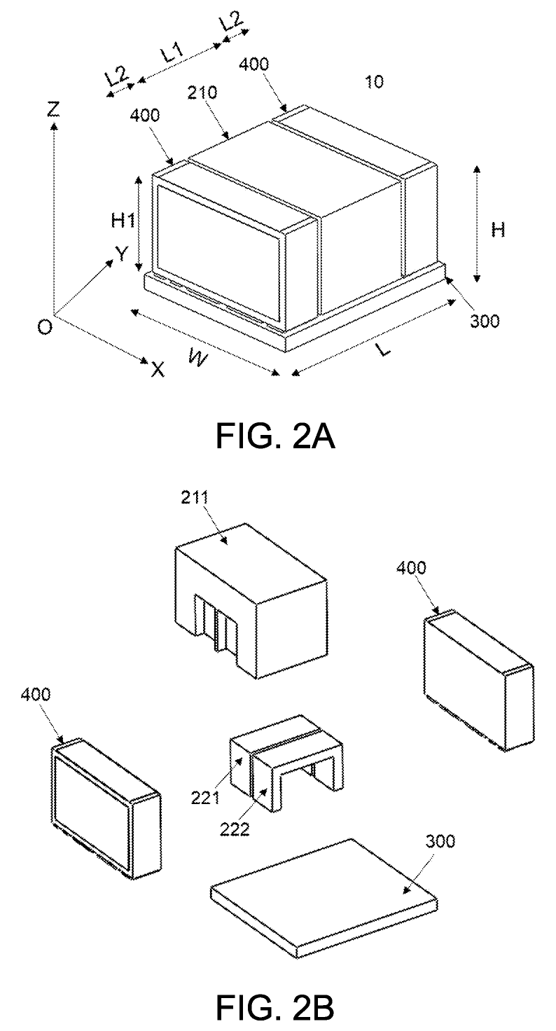

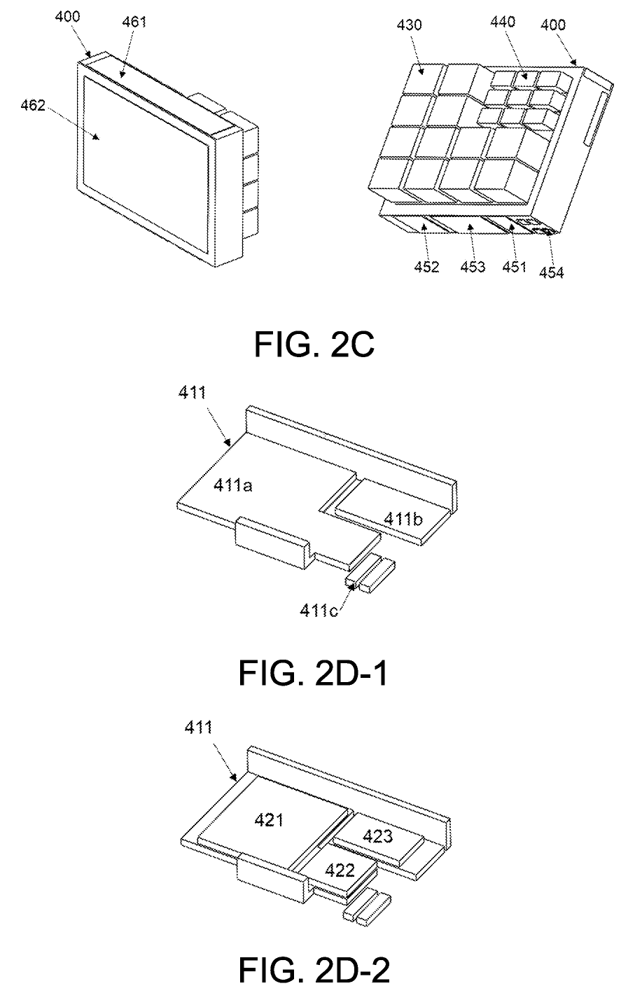

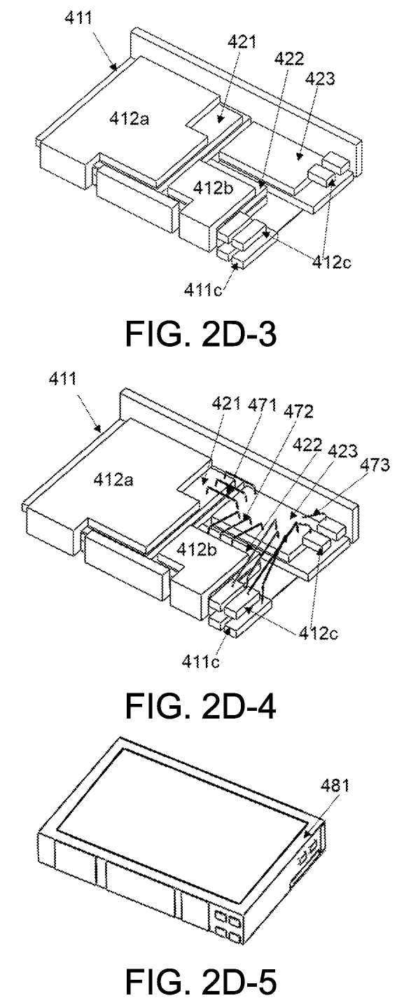

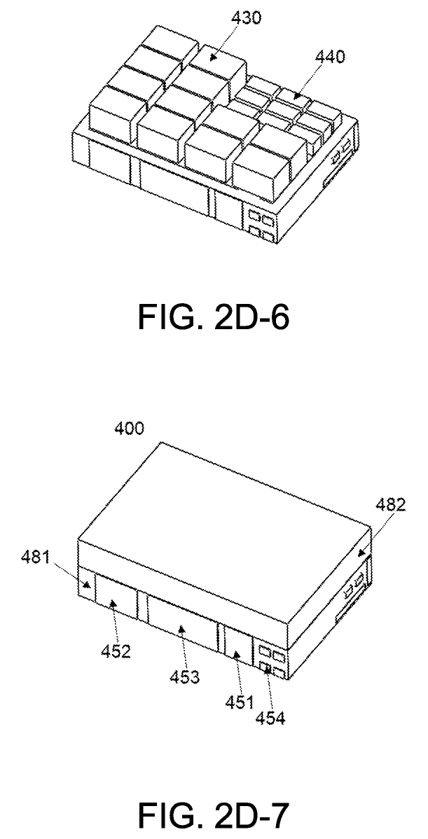

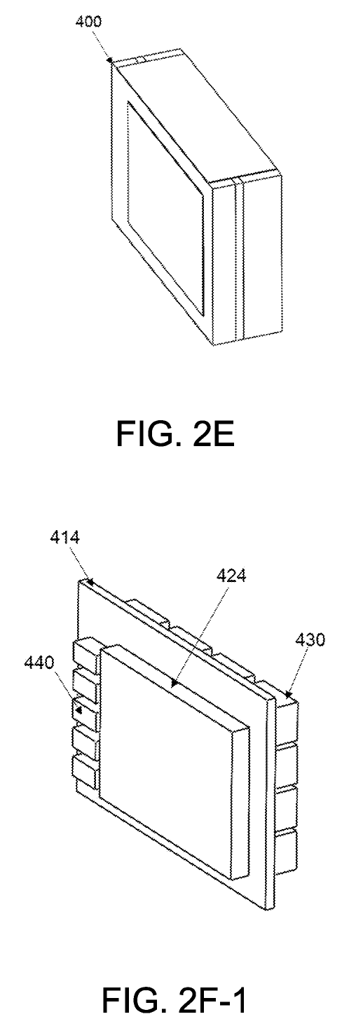

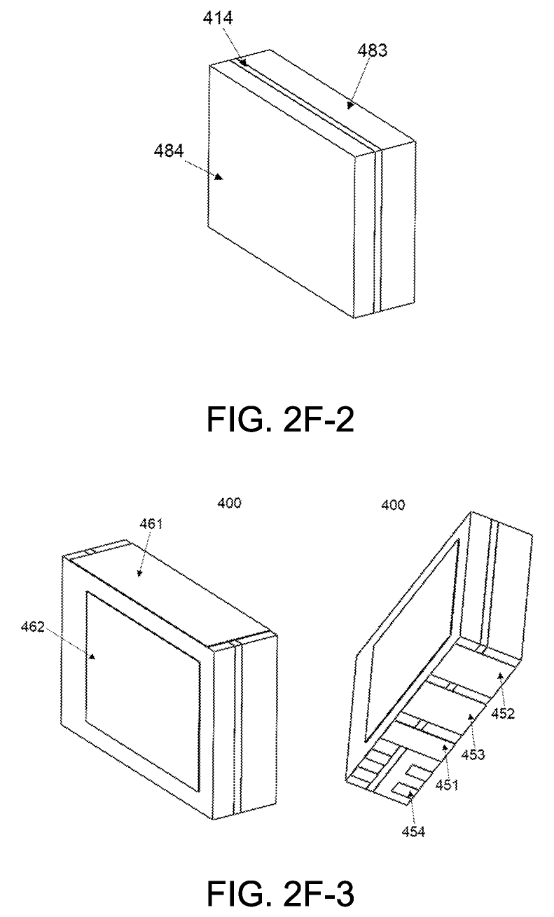

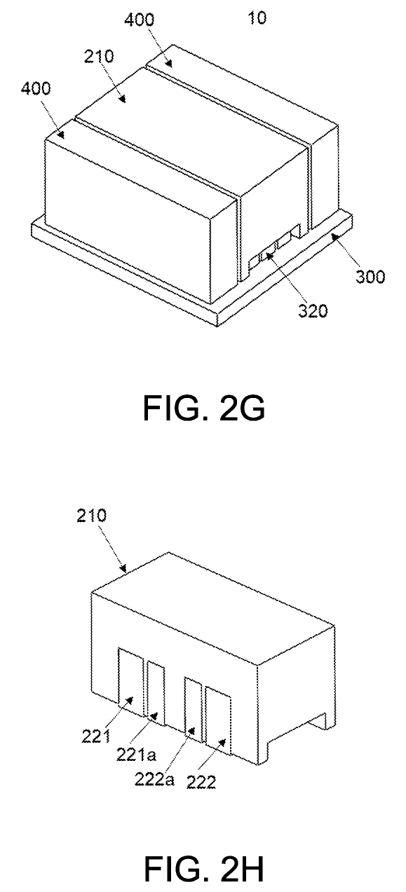

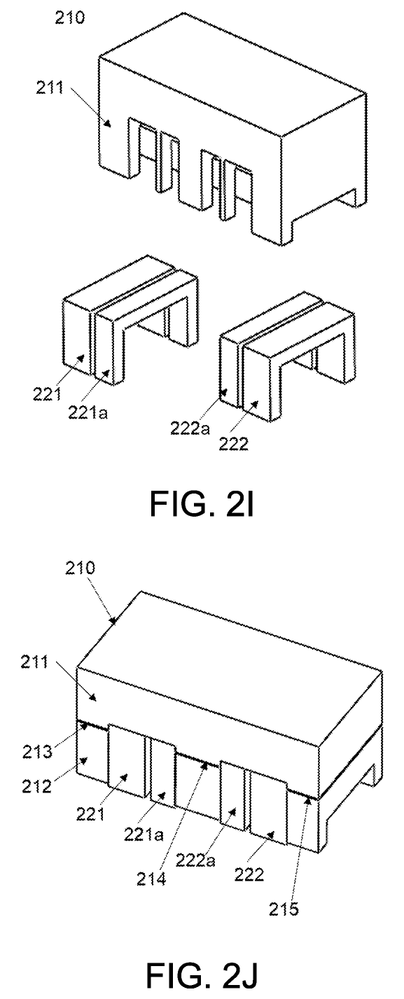

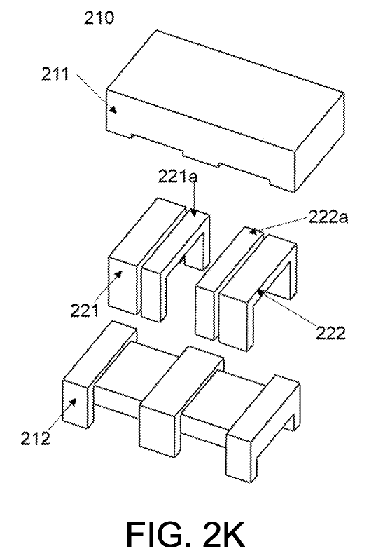

FIG. 2A shows a VRM module 10 disclosed in the present disclosure, and FIG. 2B is an exploded structural view of FIG. 2A. As shown in FIGS. 2A and 2B, the VRM module 10 includes an inductor 210, a bottom assembly 310, and two integrated power electronic components 400. The VRM module has a first side surface and a third side surface opposite to each other, and a second side surface and a fourth side surface opposite to each other. The first side surface, the second side surface, the third side surface, and the fourth side surface are arranged sequentially in a clockwise direction. The inductor 210 includes a magnetic core 211, a winding 221, and a winding 222. The inductor 210 and the integrated power electronic components 400 are respectively soldered to the top surface of the substrate 300 in a horizontal structure. A first integrated power electronic component 400, the inductor 210, and a second integrated power electronic component 400 are arranged sequentially from the second side surface to the fourth side surface of the module. The bottom assembly 310 includes the substrate 300. Preferably, the VRM module 10 is also provided without a bottom substrate. A VRM module without a bottom substrate is referred to as a power unit. In such a case, the integrated power electronic components 400 and the inductor 210 are directly arranged on a circuit board of an external component, such as a system board.

The inductor 210 includes the magnetic core 211, a first winding 221, and a second winding 222, which are integrally pressed and formed. The length L1 of the inductor 210 is approximately half of the module length L. Generally, the module length L is twice the height H. Therefore, the ratio of the length to the height of the inductor 210 is close to 1, which is conducive to improving inductor performance. Each of the first winding 221 and the second winding 222 includes a first end and a second end. The first ends and the second ends of the first winding 221 and the second winding 222 are all located on the bottom surface of the magnetic core, and are fixed to and electrically connected with the substrate 300. Preferably, the first winding 221 and the second winding 222 are “n”-shaped, each including vertical portions and a horizontal portion connecting the two vertical portions. The horizontal portion is at least partially embedded in the magnetic core 211, and the two vertical portions are at least partially exposed from the magnetic core 211. The first end of the first winding 221 and the first end of the second winding 222 are respectively electrically connected, through the substrate 300, to the integrated power electronic components 400 located on the second side surface and the fourth side surface of the magnetic core. The second end of the first winding 221 and the second end of the second winding 222 are respectively electrically connected, through the substrate 300, to the external component to supply power to the external component. The magnetic core comprises a top surface and a bottom surface opposite to each other, a first side surface and a third side surface opposite to each other, and a second side surface and a fourth side surface opposite to each other. The first side surface, the second surface, the third surface and the fourth surface of the magnetic core respectively correspond to the first side surface, the second side surface, the third side surface, and the fourth side surface of the module. Further, the current flowing through the first winding 221 flows from the second side surface to the fourth side surface, and the current flowing through the second winding 222 flows from the fourth side surface to the second side surface. Therefore, the magnetic fluxes generated by the currents in the two-phase windings cancel each other, and the two-phase inductor operates in an inverse-coupled state. This achieves a relatively small dynamic inductance, which is conducive to improving the dynamic performance of the VRM module, while also providing a relatively high steady-state inductance and high efficiency. To improve the coupling between the two-phase windings, the magnetic material between the two-phase windings is configured as a magnetic material having low magnetic permeability or as a non-magnetic material.

In this embodiment, the integrated power electronic component 400 includes opposite top and bottom surfaces and four side surfaces located between the top and bottom surfaces. The four side surfaces are a first side surface, a second side surface, a third side surface, and a fourth side surface, and these four side surfaces correspond one-to-one with the four side surfaces of the VRM module 10. The positional relationship among the first, second, third, and fourth side surfaces of the integrated power electronic component 400 is the same as the positional relationship among the four side surfaces of the VRM module. As shown in FIG. 2A, the integrated power electronic component 400 includes a length L2, a height H1, and a width. The height H1 of the integrated power electronic component 400 is greater than the length L2. However, the length and width of the integrated power electronic component 400 are not limited to those shown in FIG. 2A, and the definition of its length and width are adjusted according to the placement of the integrated power electronic component 400. In the present invention, it is sufficient that the height of the integrated power electronic component 400 is greater than at least one of its length or width. FIG. 2C is a structural schematic diagram of the two integrated power electronic components 400 in FIG. 2A. As shown in FIG. 2C, each integrated power electronic component 400 is provided with a top heat dissipation portion 461, a side heat dissipation portion 462, a first power pin 451 (VIN+), a second power pin 452 (GND), an SW pin 453, and a signal pin 454. The input filter capacitors 430 and the passive components 440 of the driver circuit are integrated on the integrated power electronic component and are closer to the silicon dies. In addition, input capacitors are arranged on the entire side surface of the integrated power electronic component, and the side surface is sufficient to accommodate more input capacitors. On one hand, the input capacitors are close to the silicon dies, which can reduce the area of the high-frequency loop and achieve a better high-frequency filtering effect. On the other hand, the arrangement of a greater number of input capacitors increases the capacitance of the input capacitors, such that a frequency of LC oscillation of the input loop is shifted away from a switching frequency of the VRM, and an amplitude of the LC oscillation is reduced, thereby reducing energy loss caused by the oscillation and improving the efficiency of the VRM.

As shown in FIGS. 2D-1-2D-7, the integrated power electronic component 400 includes a first lead frame 411, a second lead frame 412, a first MOSFET die 421, a second MOSFET die 422, a logic control die 423, a conductive medium, capacitors, and resistors. The first MOSFET die 421 and the second MOSFET die 422 are both MOSFET devices having vertical conductive channels. The logic control die 423 is used to drive and control the dies 421 and 422. Here, the first MOSFET die 421 serves as the lower switch of the integrated power electronic component, and the second MOSFET die 422 serves as the upper switch of the integrated power electronic component. The source electrode of the upper switch 422 is electrically and thermally connected with the first lead frame 411 through the conductive medium. The drain electrode of the lower switch 421 is electrically and thermally connected with the first lead frame 411 through the conductive medium. Therefore, the first lead frame 411 is configured as the SW pin of the half-bridge power electronic component. The logic control die 423 and the first lead frame 411 are only mechanically connected and are not electrically connected. In the present disclosure, MOSFETs are used merely as examples for illustration. The dies 421 and 422 are not limited to MOSFET dies and may also be SiC, GaN, MOSFET, or IGBT bare dies.

FIGS. 2D-1-2D-7 show one implementation process of the integrated power electronic component 400. The specific steps are as follows.

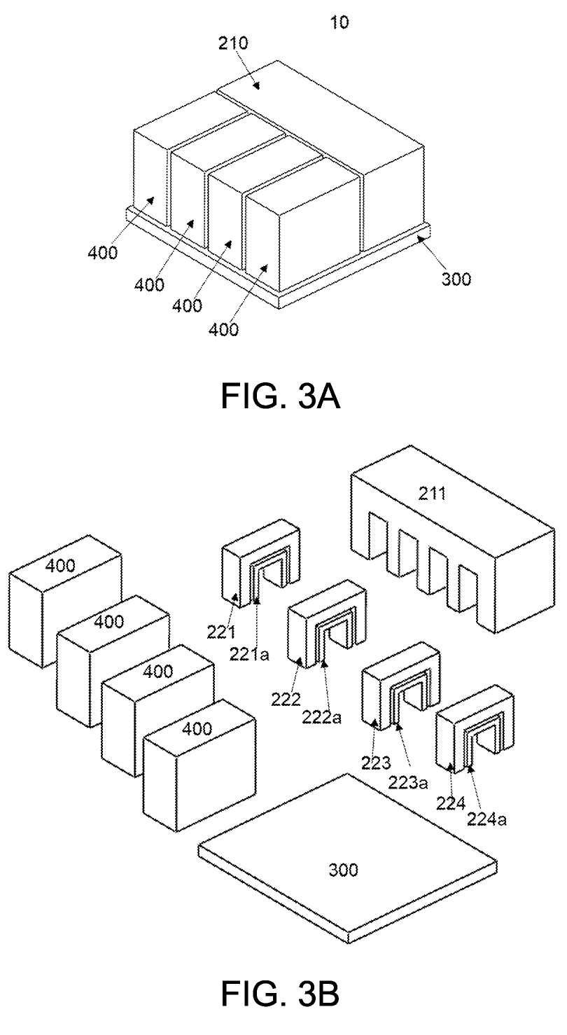

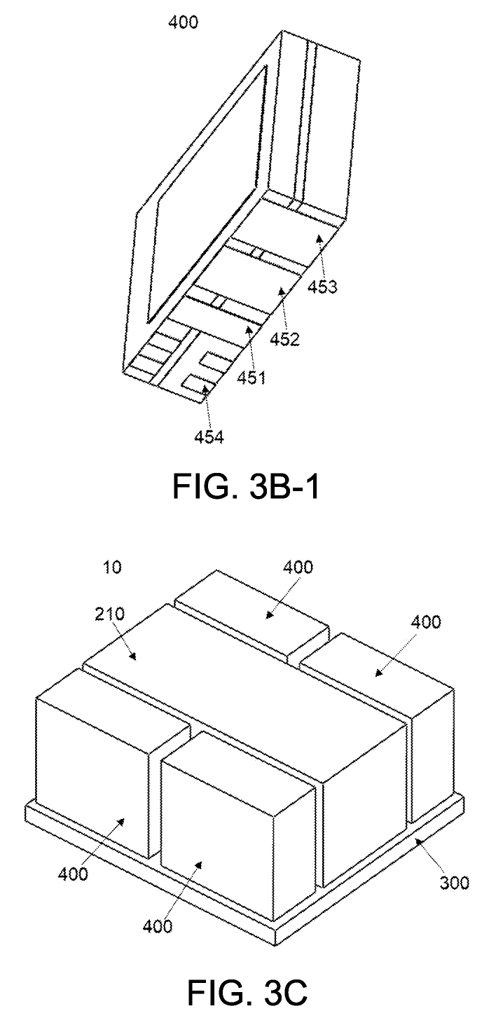

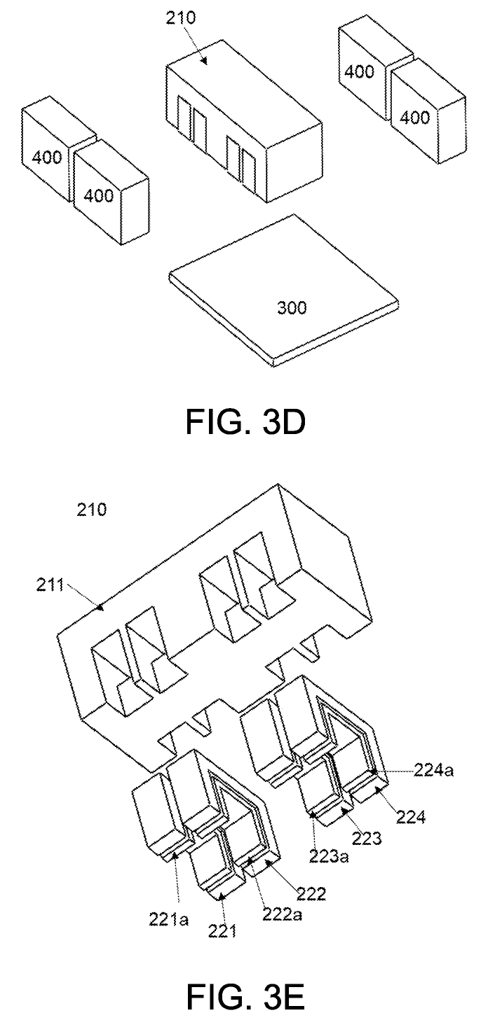

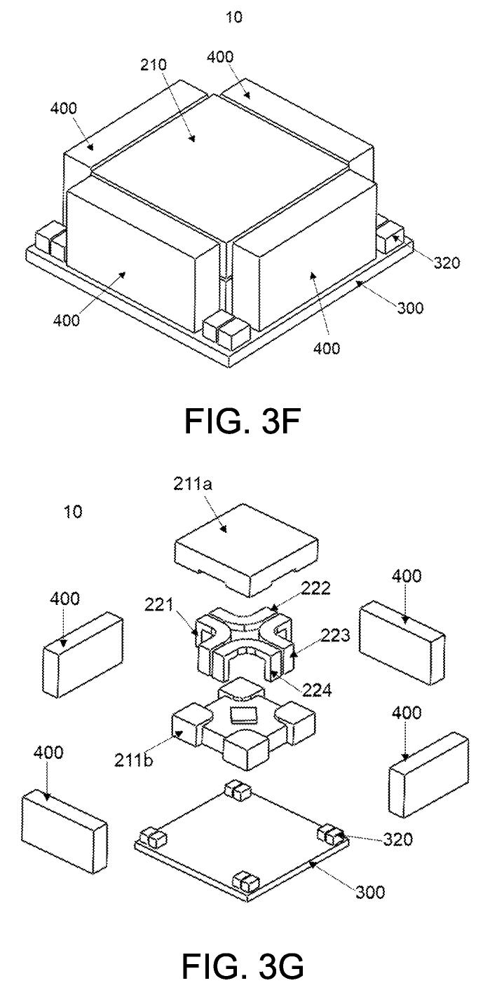

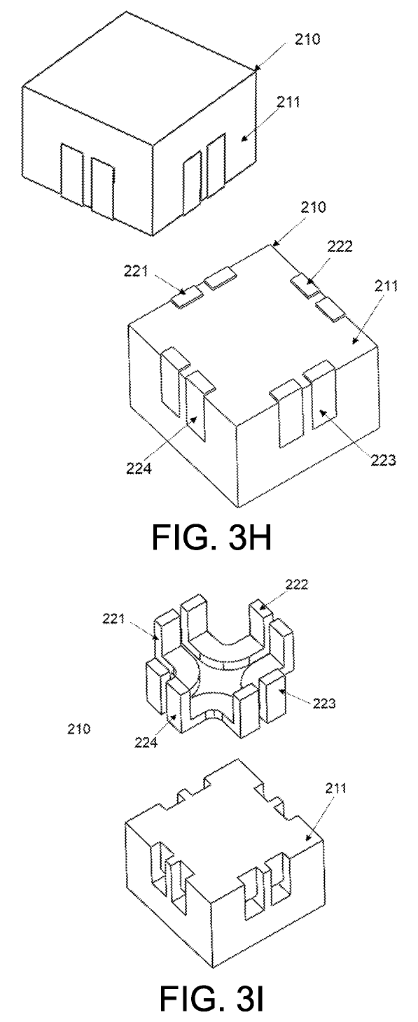

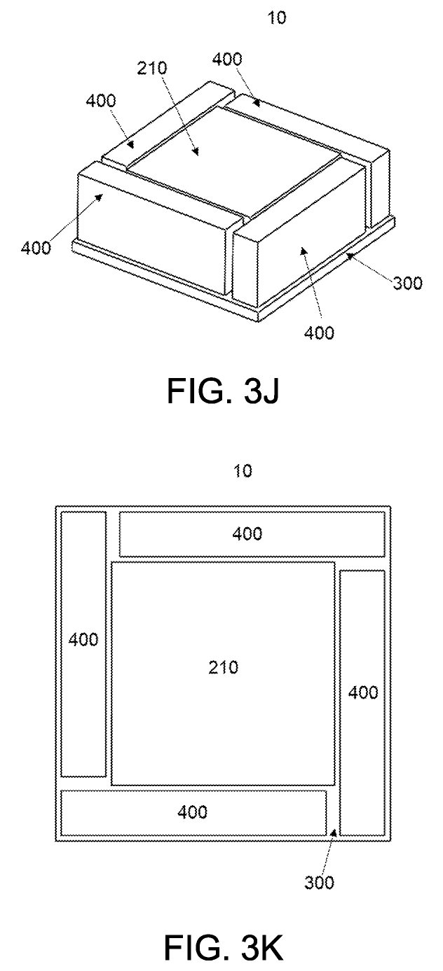

Preprocessing: silicon die preprocessing and lead frame preprocessing.
1) Silicon die preprocessing: a full wafer is diced into a plurality of silicon dies, and die testing and screening are performed according to specification requirements; alternatively, the full wafer is tested and screened prior to dicing, and only silicon dies satisfying the specification requirements are retained after dicing.
2) Lead frame preprocessing: the first lead frame 411 and the second lead frame 412 are pre-formed. The first lead frame 411 comprises a first portion 411a, a second portion 411b, and a third portion 411c (tie bars frame portions of the lead frame are omitted, and only functional portions are illustrated), as shown in FIG. 2D-1. The first portion 411a, the second portion 411b, and the third portion 411c are electrically isolated from one another. The second lead frame 412 comprises a first portion 412a, a second portion 412b, and a third portion 412c (tie bars frame portions of the lead frame are omitted, and only functional portions are illustrated), as shown in FIG. 2D-3. The first portion 412a, the second portion 412b, and the third portion 412c of the second lead frame 412 are electrically isolated from one another.

First step: die attachment, bonding material coating, die positioning and curing.
1) As shown in FIG. 2D-1, the first lead frame 411 is provided. A conductive medium, such as solder, silver paste, or conductive epoxy resin adhesive, is printed on the top surface of the first lead frame 411. The conductive medium is not shown in the figure. The preprocessed dies 421, 422, and 423 are attached to the top surface of the first lead frame 411, as shown in FIG. 2D-2.
   Here, the bottom surfaces of the two dies are electrically and thermally connected with the first lead frame 411 through the conductive medium. The conductive medium is used to ensure mechanical stability between the dies and the lead frame, as well as good electrical and thermal conduction.
2) A conductive medium is further printed or dispensed above the dies shown in FIG. 2D-2, and the second lead frame 412 is arranged above the dies, as shown in FIG. 2D-3, so that the second lead frame 412 is electrically and thermally connected with the top surfaces of the dies through the conductive medium.
   Here, the first portion 412a of the second lead frame 412 is electrically and thermally connected with the top surface of the first MOSFET die 421 through the conductive medium. The second portion 412b of the second lead frame 412 is electrically and thermally connected with the top surface of the second MOSFET die 422 through the conductive medium. The top surface of the first MOSFET die 421, which serves as the lower switch of the half-bridge power electronic component, is configured as the source electrode of the lower switch. Therefore, the first portion 412a of the second lead frame 412 is configured as the input negative terminal GND. The top surface of the second MOSFET die 422, which serves as the upper switch of the half-bridge power electronic component, is configured as the drain electrode of the upper switch. Therefore, the second portion 412b of the second lead frame 412 is configured as the input positive terminal VIN.

Second step: wire bonding to implement electrical connection.

As shown in FIG. 2D-4, after attachment of the second lead frame 412 is completed, wire bonding is performed between the logic control die 423 and the first MOSFET die 421, the second MOSFET die 422, the third portion 411c of the first lead frame, and the third portion 412c of the second lead frame, so as to implement signal transmission between the logic control signals and the two switching dies.

Here, a first wire 471 electrically connects the logic control die 423 to the first MOSFET die 421 and is used to drive and control turn-on and turn-off of the lower switch. A second wire 472 electrically connects the logic control die 423 to the second MOSFET die 422 and is used to drive and control turn-on and turn-off of the upper switch. A third wire 473 electrically connects the logic control die 423 to the third portion 411c of the first lead frame 411 and the third portion 412c of the second lead frame 412 and is used for signal transmission between the logic control die 423 and a system controller.

Third step: post-processing and protection, molding, trimming and forming, plating, and marking.
1) The integrated power electronic component on which wire bonding has been completed in FIG. 2D-4 needs to be molded and encapsulated with epoxy molding compound (EMC) at a high temperature to form a protective layer having a certain thickness and to form a first molded body 481, as shown in FIG. 2D-5.
   The protective layer is also formed by embedding.
2) At least two wiring layers are arranged on the surface of the molding, so as to alternately lead the input positive terminal VIN+ and the input negative terminal GND out to the surface of the first molded body 481, as shown in FIG. 2D-5. The capacitors 430 and other passive components 440 are mounted on the surface of the first molded body 481, as shown in FIG. 2D-6. Then, the capacitors and passive components are also molded through a secondary molding process to form a second molded body 482, as shown in FIG. 2D-7, thereby protecting the capacitors and other passive components from mechanical impact and mechanical stress.
3) Redundant structures at the periphery of the lead frames and non-functional tie-bar portions of the leadframe tie bar are removed. A plating process is performed at positions where the signal pins 454, the first power pins 451, the second power pins 452, and the SW pins 453 need to be provided, so as to perform surface plating on these pins and provide anti-oxidation protection.
4) The top heat dissipation portion 461 and the side heat dissipation portion 462 on the surface of the integrated power electronic component 400 are formed by leading the internal ground pin GND or the SW pin out to the surface of the integrated power electronic component. Here, both the SW pin and the ground pin GND are paths through which large current flows and are also composed of large metal materials, thereby having good thermal conductivity. Therefore, both the SW pins and the ground pins GND serve as high-current paths and are formed of large metal structures having favorable thermal conductivity. Accordingly, electrical conduction and heat conduction are multiplexed, thereby improving the power density of the module. In addition, when a heat sink is provided, the top heat dissipation portion 461 and the side heat dissipation portion 462 are required to be electrically isolated from each other.

Thus, the integrated power electronic component having complete functions is manufactured.

The present disclosure further proposes another preferred implementation. The lead frames, dies, and capacitors are all embedded in a substrate by an embedding method, so as to simplify the manufacturing process of the integrated power electronic component 400.

In the embodiment shown in FIG. 2E, the silicon die adopts a planar Driver MOSFET, and its logic control portion and power portion have been integrated into the integrated die 424. A bottom surface of the die electrically connected with the internal substrate 414 is provided with BUMP pins. FIGS. 2F-1-2F-3 show another implementation process of the integrated power electronic component 400 in this embodiment. The detailed steps are as follows.

First step: as shown in FIG. 2F-1, the integrated die 424 and other passive components 440 are mounted on a first surface of the internal substrate 414, and the input capacitors 430 are mounted on a second surface of the internal substrate 414. In addition, before being mounted, the integrated die 424 is also subjected to backside grinding and thinning, and then diced, tested, and screened. Thinning is performed to improve the efficiency of subsequent dicing and to improve space utilization.

Second step: the semi-finished integrated power electronic component obtained after components are mounted on both sides in the first step is subjected to a double-sided molding process, thereby forming a third molded body 483 and a fourth molded body 484 to protect the stability and reliability of the integrated die, the input capacitors, and the other passive components, as shown in FIG. 2F-2.

Third step: a plating process is performed at positions where pins need to be provided to form the first power pins 451, the second power pins 452, the SW pins 453, and the signal pins 454, as shown in FIG. 2F-3, thereby protecting the pins from oxidation. Meanwhile, the top heat dissipation portion 461 and the side heat dissipation portion 462 are formed by plating. The top heat dissipation portion 461 is thermally connected with metal in the internal substrate 414, and the side heat dissipation portion 462 is thermally connected with the top surface of the die, thereby further improving the heat dissipation performance of the integrated power electronic component.

FIG. 2G shows another embodiment of the VRM module 10 of FIG. 2A. The difference between the embodiment shown in FIG. 2G and the embodiment shown in FIG. 2A lies in that the structure of the inductor 210 is different, and the embodiment shown in FIG. 2G includes output capacitors 320. FIG. 2H is a structural schematic diagram of the inductor in FIGS. 2G, and 2I is an exploded schematic diagram of the inductor in FIG. 2G. As shown in FIGS. 2G-2I, the inductor 210 in this embodiment is additionally provided with auxiliary windings 221a and 222a. The auxiliary winding 221a is coupled to the main winding 221, and the auxiliary winding 222a is coupled to the main winding 222. Electrical isolation is implemented between the main winding 221 and the auxiliary winding 221a and between the main winding 222 and the auxiliary winding 222a. To improve the coupling coefficient between the mutually coupled main winding and auxiliary winding, a magnetic core material having low magnetic permeability or a non-magnetic material is arranged between the main winding and the auxiliary winding. The arrangement of the auxiliary windings can implement TLVR technology, further reduce the dynamic inductance of the VRM module, and improve the dynamic performance of the VRM module. In addition, the bottom of the magnetic core in this embodiment is provided with grooves, which are used to accommodate the output capacitors 320 arranged on the bottom substrate 300. The arrangement of these output capacitors can further improve the dynamic performance of the VRM module.

FIG. 2J shows another preferred implementation of the inductor 210 in FIGS. 2G, and 2K is an exploded structural view of FIG. 2J. As shown in FIGS. 2J and 2K, the inductor 210 in this embodiment includes a first magnetic core 211, a second magnetic core 212, a first main winding 221, a first auxiliary winding 221a, a second main winding 222, and a second auxiliary winding 222a. The first main winding 221 and the first auxiliary winding 221a are arranged in the same window of the magnetic core so as to have a strong coupling coefficient. The second main winding 222 and the second auxiliary winding 222a are arranged in another window of the magnetic core so as to have a strong coupling coefficient. Both the first magnetic core 211 and the second magnetic core 212 are made of metal magnetic powder cores. Air gaps 213, 214, and 215 are provided on the mating surface between the first magnetic core 211 and the second magnetic core 212, and the air gaps 213, 214, and 215 are made as small as possible to maintain sufficiently high inductance. In a preferred solution, both the first magnetic core 211 and the second magnetic core 212 are configured as high-permeability ferrite materials, and the length of the air gap 214 is greater than the lengths of the air gaps 213 and 215, so as to maintain coupling between the first main winding and the second main winding. In this embodiment, the two-phase main windings operate in an inverse-coupled state, and TLVR technology can be implemented at the same time.

Compared with a VRM module in the prior art, the module proposed in the present disclosure eliminates power electrical connectors. On one hand, this eliminates losses on the power electrical connectors and improves the conversion efficiency of the VRM module. On the other hand, it saves space within the module, allowing more input capacitors to be arranged in the module, thereby eliminating efficiency loss and electromagnetic interference caused by LC resonance in the input loop, and providing a better filtering effect and a lower input voltage ripple. In addition, the inductor has a small width-to-thickness ratio, which can further improve the performance of the inductor and help improve the conversion efficiency of the VRM module. The inductor implement an inverse-coupled design, a TLVR inductor design, or a design in which TLVR is added on the basis of inverse coupling, thereby achieving optimal dynamic performance while also improving efficiency. The integrated power electronic component proposed in the present disclosure enables the inductor and the integrated power electronic component in the VRM module adopting a horizontal structure to have substantially the same height, or the top surfaces of the inductor and the integrated power electronic component are flush with each other, such that the VRM module has a substantially planar upper surface. Furthermore, the VRM module may employ air cooling, liquid cooling, or immersion liquid cooling, while simultaneously satisfying heat dissipation requirements of both the integrated power electronic component and the inductor. On the basis of satisfying heat dissipation requirements, the output current of a single VRM module can be increased, thereby increasing the output power of a single VRM module. The horizontal structure reduces the use of printed circuit boards, lowers costs, and improves product competitiveness. By changing the sandwich stacking in the height direction into two-layer stacking, manufacturing becomes simpler and mass production becomes easier. Under the same power, the size in the XY directions can be further reduced, and the current density and power density can be further increased.

FIG. 3A shows a four-phase TLVR module according to the present disclosure, and FIG. 3B is an exploded structural view of FIG. 3A. As shown in FIGS. 3A and 3B, the four-phase TLVR module includes a substrate 300, an inductor 210, and four integrated power electronic components 400. The width direction of the integrated power electronic components 400 is parallel to the first side surface and the third side surface of the substrate 300, or of the circuit board of an external component. The first side surface, the second side surface, the third side surface, and the fourth side surface of the substrate are respectively the first side surface, the second side surface, the third side surface, and the fourth side surface of the power module. The length direction of the integrated power electronic components 400 is parallel to the second side surface, and the integrated power electronic components 400 are arranged adjacent to the second side surface of the substrate 300. The inductor 210 is arranged along the fourth side surface of the substrate 300. The inductor 210 includes a magnetic core 211 and windings. These windings include a first main winding 221, a first auxiliary winding 221a, a second main winding 222, a second auxiliary winding 222a, a third main winding 223, a third auxiliary winding 223a, a fourth main winding 224, and a fourth auxiliary winding 224a. These main windings and auxiliary windings are all “n”-shaped. The main windings and their corresponding auxiliary windings are stacked in the vertical direction, and the main windings and their corresponding auxiliary windings are electrically isolated from each other. The integrated power electronic component 400 in this embodiment is the same as the integrated power electronic component 400 in Embodiment 1. To improve efficiency, the pins of the integrated power electronic component are also slightly adjusted as shown in FIG. 3B-1, that is, the positions of the SW pin 453 and the second power pin 452 of the integrated power electronic component in Embodiment 1 are exchanged, so as to reduce the distance between the SW pin of the integrated power electronic component and the inductor pin, thereby reducing DC resistance and improving efficiency.

FIG. 3C shows another preferred implementation of FIG. 3A, FIG. 3D is an exploded structural view of FIGS. 3C, and 3E is an exploded structural view of the inductor 210 in FIG. 3D. As shown in FIGS. 3C-3E, the four integrated power electronic components 400 in this embodiment are arranged in a 2*2 array at the four corners of the substrate 300. The integrated power electronic components here may use any embodiment of the integrated power electronic component shown in the present disclosure. The inductor 210 is arranged in the middle of the substrate 300 and extends from the first side surface of the substrate 300 to the third side surface of the substrate 300. The inductor 210 includes a magnetic core 211, a first main winding 221, a first auxiliary winding 221a, a second main winding 222, a second auxiliary winding 222a, a third main winding 223, a third auxiliary winding 223a, a fourth main winding 224, and a fourth auxiliary winding 224a. The main windings and their corresponding auxiliary windings are stacked in the vertical direction, and the main windings and their corresponding auxiliary windings are strongly coupled and electrically isolated from each other. The auxiliary windings are arranged to implement TLVR technology. A magnetic material having low magnetic permeability or a non-magnetic material is arranged between the first main winding 221 and the second main winding 222 to implement inverse coupling between the first main winding and the second main winding. A magnetic material having low magnetic permeability or a non-magnetic material is arranged between the third main winding 223 and the fourth main winding 224 to implement inverse coupling between the third main winding and the fourth main winding. Meanwhile, a certain distance is ensured between the second main winding 222 and the third main winding 223, so as to ensure weak coupling between the first main winding or the second main winding and the third main winding or the fourth main winding. That is, overall, a solution of two two-phase inverse-coupled structures plus TLVR technology is implemented to achieve better dynamic performance.

FIG. 3F shows another preferred implementation of FIGS. 3A, and 3G is an exploded structural view of FIG. 3F. As shown in FIGS. 3F and 3G, the four integrated power electronic components 400 in this embodiment are respectively arranged adjacent to the four side surfaces of the substrate and surround the inductor 210. The integrated power electronic components can use any embodiment of the integrated power electronic component described in the present disclosure. Output capacitors 320 are further arranged at the four corners of the substrate 300. The inductor 210 includes a magnetic core 211, a first winding 221, a second winding 222, a third winding 223, and a fourth winding 224. The magnetic core 211 includes a first magnetic core 211a and a second magnetic core 211b. The magnetic core 211 also includes a first side surface, a second side surface, a third side surface, and a fourth side surface, which respectively correspond to the four side surfaces of the module. The first winding 221 passes through the magnetic core from the second side surface of the magnetic core 211 and extends to the third side surface. The first winding 221 is electrically connected with the SW pin of the integrated power electronic component 400 through the substrate 300 on the second side surface, and supplies power to the load through the substrate 300 on the third side surface. The second winding 222 passes through the magnetic core from the third side surface of the magnetic core 211 and extends to the fourth side surface. The second winding 222 is electrically connected with the SW pin of the integrated power electronic component 400 through the substrate 300 on the third side surface, and supplies power to the load through the substrate 300 on the fourth side surface. The third winding 223 passes through the magnetic core from the fourth side surface of the magnetic core 211 and extends to the first side surface. The third winding 223 is electrically connected with the SW pin of the integrated power electronic component 400 through the substrate 300 on the fourth side surface, and supplies power to the load through the substrate 300 on the first side surface. The fourth winding 224 passes through the magnetic core from the first side surface of the magnetic core 211 and extends to the second side surface. The fourth winding 224 is electrically connected with the SW pin of the integrated power electronic component 400 through the substrate 300 on the first side surface, and supplies power to the load through the substrate 300 on the second side surface. Because the current in each winding flows from the SW pin to the load, the magnetic fluxes generated by the currents flowing through the four-phase windings in the inductor cancel each other, and the inductor constitutes a four-phase inverse-coupled inductor. In this embodiment, the four-phase inductor adopts an assembly process. All magnetic posts of the magnetic core are provided with air gaps, and the air gap in the center post is longer than the air gaps in the side posts. As a result, the four-phase inverse-coupled inductor has a relatively low dynamic inductance to achieve fast dynamic performance and has a relatively high steady-state inductance to achieve high conversion efficiency.

FIG. 3H shows another preferred implementation of the inductor 210 in FIGS. 3F, and 3I is an exploded structural view of FIG. 3H. As shown in FIGS. 3H and 3I, the inductor described in this embodiment is an integrally formed inductor. A magnetic material having low magnetic permeability or a non-magnetic material is arranged between windings to enhance coupling among the four-phase windings, thereby reducing the dynamic inductance of the inductor and improving the dynamic performance of the VRM module. This embodiment adopts an integral forming method to manufacture the four-phase inductor. Compared with the aforementioned assembled four-phase inductor, the manufacturing process is simpler, and the flatness tolerance of the pins is smaller, which is conducive to soldering of the inductor.

FIG. 3J shows another preferred implementation similar to the implementation shown in FIGS. 3F, and 3K is a top view of FIG. 3J. As shown in FIGS. 3J and 3K, in order to fully utilize the space around the inductor, the four integrated power electronic components 400 are arranged end to end and arranged close to the periphery of the substrate, that is, the gaps between adjacent integrated power electronic components 400 are reduced. The inductor 210 is arranged in the center of the top surface of the substrate 300, and the integrated power electronic components 400 surround the inductor. From the top view, the space on the substrate 300 is occupied by the inductor 210 and the integrated power electronic components 400, that is, the space utilization is higher, and the power density can be further improved. Further, grooves may be provided at the bottom of the magnetic core to accommodate the output capacitors 320 arranged on the substrate 300, which are not shown in this embodiment.

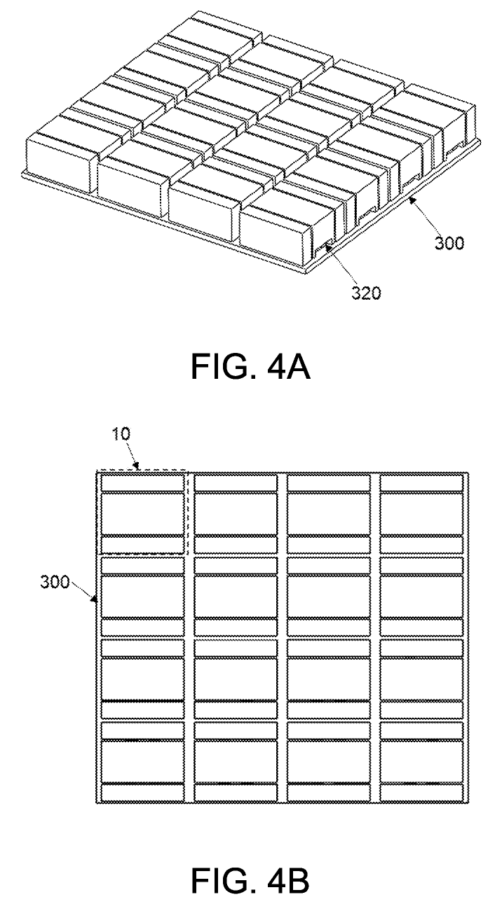

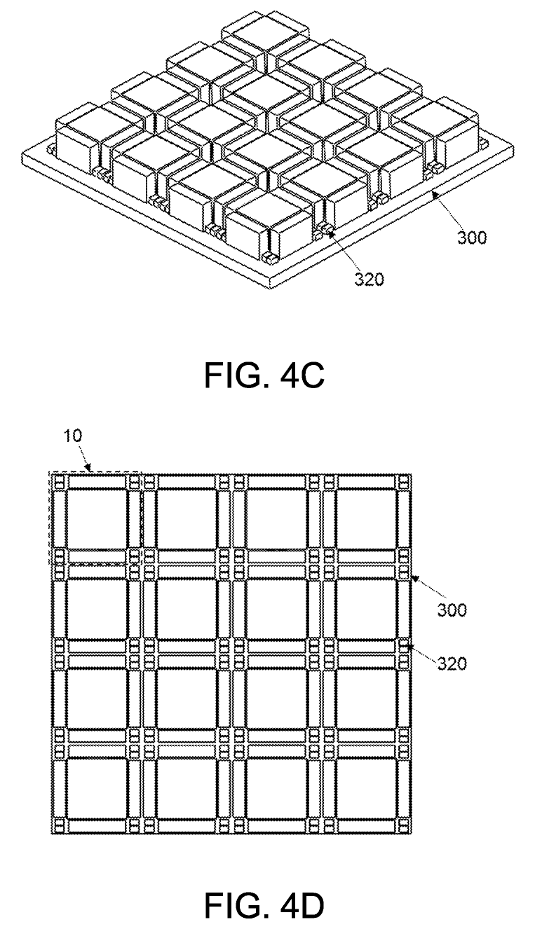

FIG. 4A shows an arrangement manner in which the module according to the embodiments of the present disclosure is applied to a vertical power supply scenario, and FIG. 4B is a top view of FIG. 4A. As shown in FIGS. 4A and 4B, a plurality of two-phase VRM modules 10 are arranged in an M*N array, where both M and N are integers greater than 1. That is, M*N two-phase VRM modules 10 are used in this power supply solution. The M*N two-phase VRM modules are a two-phase non-coupled solution, a two-phase inverse-coupled solution, or a two-phase TLVR solution. If a two-phase TLVR solution is adopted, the solution is further configured as 2M*N/2x 2x-phase TLVRs solution, where x is an integer greater than or equal to 1, to provide a larger current and a faster transient response.

FIG. 4C shows another arrangement manner in which the module according to the embodiments of the present disclosure is applied to a vertical power supply scenario, and FIG. 4D is a top view of FIG. 4C. As shown in FIGS. 4C and 4D, the four-phase VRM modules 10 are arranged in an M*N array to form M*N four-phase inverse-coupled modules power supply solution. The M*N four-phase VRM modules share one substrate 300 to provide a larger current and a faster transient response.

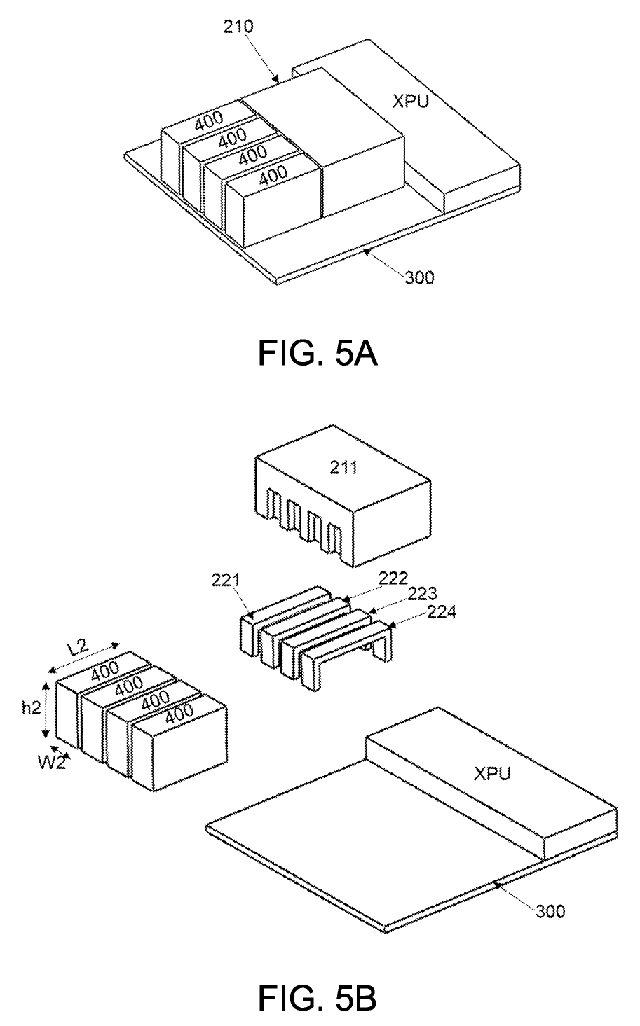

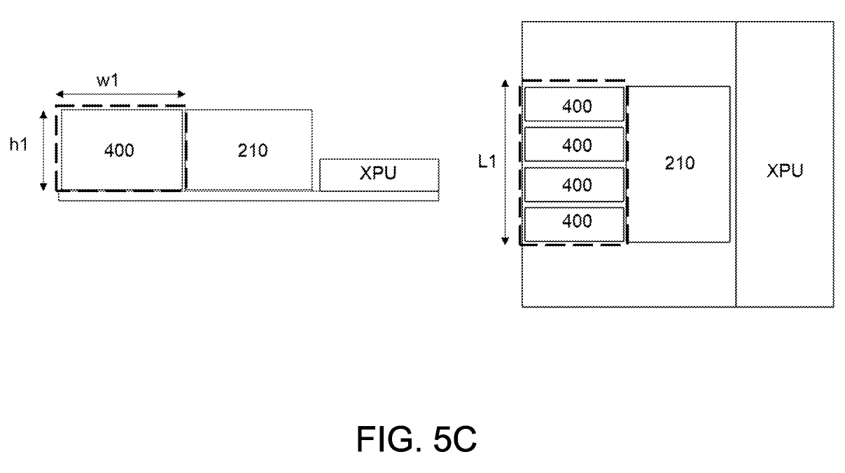

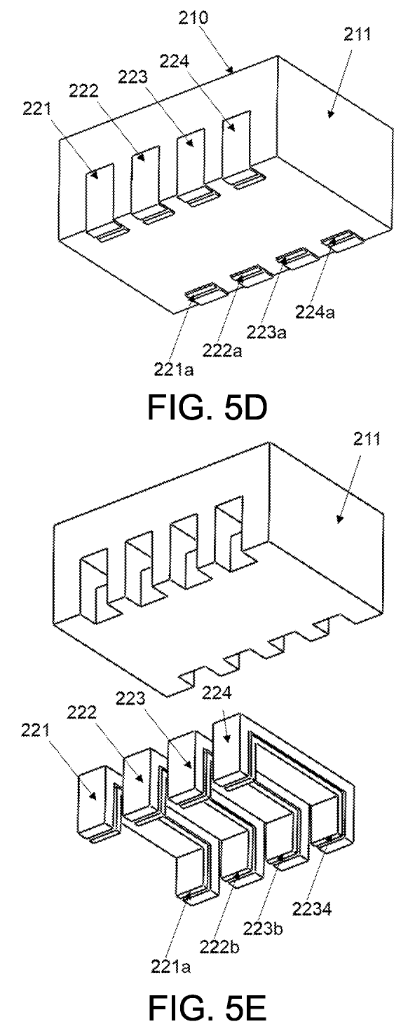

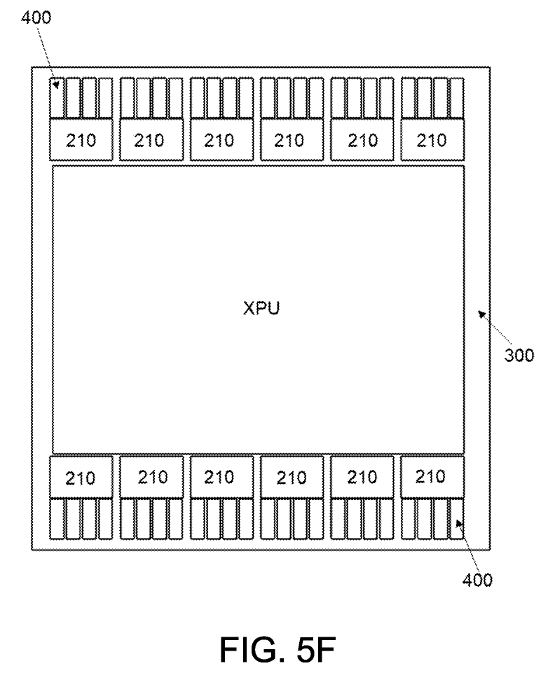

FIG. 5A shows an innovative manner of a conventional discrete application in the application scenario described in FIG. 1D, that is, the integrated power electronic components 400 according to the present disclosure are used to replace conventional discrete Dr. MOS devices, thereby improving space utilization and power density. FIG. 5B is an exploded structural view of FIGS. 5A, and 5C is a side view and a top view of FIG. 5A. As shown in FIGS. 5A-5C, four integrated power electronic components 400, an inductor 210, and a load XPU are arranged horizontally. The integrated power electronic components 400 here may be any integrated power electronic component 400 described in the present disclosure. The inductor 210 includes a magnetic core 211, a first main winding 221, a second main winding 222, a third main winding 223, and a fourth main winding 224, which are integrally pressed and formed. Compared with the space region L1*W1*h1 above the Dr. MOS that is wasted in the prior art, the power electronic component in this embodiment fully utilizes this space region after integrating the capacitors, thereby improving the power density of the power module.

FIG. 5D is a structural schematic diagram of another implementation of the inductor in FIGS. 5A, and 5E is an exploded structural view of the inductor in FIG. 5D. As shown in FIGS. 5D and 5E, the inductor 210 includes a magnetic core 211, a first main winding 221, a first auxiliary winding 221a, a second main winding 222, a second auxiliary winding 222a, a third main winding 223, a third auxiliary winding 223a, a fourth main winding 224, and a fourth auxiliary winding 224a. The main windings and their corresponding auxiliary windings are stacked in the vertical direction to achieve strong coupling and implement TLVR technology. The main windings and their corresponding auxiliary windings are electrically isolated from each other.

FIG. 5F shows a complete form of the power supply solution described in FIG. 5A. As shown in FIG. 5F, more integrated power electronic components 400 and inductors 210 shown in FIG. 5A are arranged around or on two sides of the XPU to provide a higher-power power supply and meet power supply requirements with higher power density.

The terms “equal,” “same,” or “equivalent”, “coplanar”, or “perpendicular” disclosed in the present invention all need to take into account engineering parameter distribution, with an error distribution within ±30%.

The embodiments in this specification are described in a progressive manner. Each embodiment focuses on differences from the other embodiments, and identical or similar portions among the embodiments may be referenced with respect to one another.

The foregoing description of the disclosed embodiments enables a person skilled in the art to implement or use the present disclosure. Various modifications to these embodiments will be apparent to a person skilled in the art. The general principles defined herein may be implemented in other embodiments without departing from the spirit or scope of the present disclosure. Therefore, the present disclosure is not limited to the embodiments shown herein, but should be accorded the broadest scope consistent with the principles and novel features disclosed herein.

What is claimed is:

1. An integrated power electronic component, comprising:
an upper switch and a lower switch, wherein the upper switch and the lower switch are electrically connected in series;
four side surfaces, and a top surface and a bottom surface opposite to each other, wherein the top surface is provided with a top heat dissipation portion, one of the side surfaces is provided with a side heat dissipation portion, and the bottom surface is provided with pins;
wherein a distance between the top surface and the bottom surface is a height of the integrated power electronic component, the top surface and/or the bottom surface of the integrated power electronic component is rectangular, with two adjacent sides of a rectangle respectively corresponding to a length direction and a width direction of the integrated power electronic component, and the height is greater than the length and/or the width.

2. The integrated power electronic component according to claim 1, wherein the integrated power electronic component further comprises a capacitor, the capacitor is arranged on a side surface of the integrated power electronic component, and the capacitor and the side heat dissipation portion are arranged opposite to each other.

3. The integrated power electronic component according to claim 1, wherein the pins arranged on the bottom surface comprise a first power pin, a second power pin, an SW pin, and a signal pin.

4. The integrated power electronic component according to claim 3, wherein, on the bottom surface of the integrated power electronic component, the second power pin, the SW pin, the first power pin, and the signal pin are sequentially arranged along a same direction, or the SW pin, the second power pin, the first power pin, and the signal pin are sequentially arranged along the same direction.

5. The integrated power electronic component according to claim 3, wherein a signal pin is arranged on a side surface of the integrated power electronic component, and the signal pin arranged on the bottom surface and the signal pin arranged on the side surface are arranged adjacent to each other.

6. The integrated power electronic component according to claim 3, wherein the top heat dissipation portion is electrically connected with the SW pin or the second power pin, and the side heat dissipation portion is electrically connected with the SW pin or the second power pin.

7. The integrated power electronic component according to claim 1, comprising:
a first lead frame and a second lead frame, each comprising a first portion, a second portion, and a third portion;
a first switching die and a second switching die, both arranged between the first lead frame and the second lead frame;
wherein a bottom surface of the first switching die and a bottom surface of the second switching die are electrically connected through the first lead frame and thermally connected with the first lead frame respectively , a top surface of the first switching die is electrically connected and thermally connected with the first portion of the second lead frame, and a top surface of the second switching die is electrically connected and thermally connected with the second portion of the second lead frame;
wherein the integrated power electronic component further comprises a logic control die and wires.

8. The integrated power electronic component according to claim 7, wherein the wires comprise a first wire, a second wire, and a third wire; the first wire electrically connects the logic control die and the first switching die; the second wire electrically connects the logic control die and the second switching die; and the third wire electrically connects the logic control die with the third portion of the first lead frame and the third portion of the second lead frame.

9. The integrated power electronic component according to claim 8, wherein the logic control die is arranged on the second portion of the first lead frame.

10. The integrated power electronic component according to claim 7, wherein the integrated power electronic component further comprises a first molded body, and the first lead frame, the second lead frame, the first switching die, the second switching die, the logic control die, and the wires are located in the first molded body.

11. The integrated power electronic component according to claim 10, wherein the first molded body comprises a top surface and a bottom surface opposite to each other and four side surfaces located between the top surface and the bottom surface; the top surface and the bottom surface of the first molded body are both rectangular and each comprise a long side and a short side; two opposite side surfaces corresponding to two long sides of the top surface and the bottom surface are respectively provided with the side heat dissipation portion and a capacitor; and the top surface of the first molded body is provided with the top heat dissipation portion.

12. The integrated power electronic component according to claim 11, wherein the integrated power electronic component further comprises a second molded body, and the capacitor is located in the second molded body.

13. The integrated power electronic component according to claim 7, wherein the integrated power electronic component further comprises a substrate, a capacitor, and other passive components, and the first lead frame, the second lead frame, the first switching die, the second switching die, the logic control die, the wires, the capacitor, and the other passive components are embedded in the substrate.

14. The integrated power electronic component according to claim 7, wherein the first portion, the second portion, and the third portion of the first lead frame are electrically isolated from one another, and the first portion, the second portion, and the third portion of the second lead frame are electrically isolated from one another.

15. The integrated power electronic component according to claim 1, comprising:
a substrate comprising a first surface and a second surface opposite to each other;
an integrated die comprising a logic control portion and a power switching portion;
a capacitor and other passive components;
wherein the integrated die and the other passive components are arranged on the first surface of the substrate, and the capacitor is arranged on the second surface of the substrate;
a third molded body configured to encapsulate the first surface of the substrate, the integrated die, and the other passive components;
a fourth molded body configured to encapsulate the second surface of the substrate and the capacitor; and
a first power pin, a second power pin, an SW pin, and a signal pin, all arranged on the bottom surface of the integrated power electronic component, wherein the bottom surface is perpendicular to the substrate.

16. A method for manufacturing the integrated power electronic component according to claim 7, comprising:
a preprocessing step, comprising silicon die preprocessing and lead frame preprocessing, wherein the silicon die preprocessing is performed to obtain the first switching die, the second switching die, and the logic control die that satisfy specifications, and the lead frame preprocessing is performed to preform the first lead frame and the second lead frame;
a first step: arranging a conductive medium on a top surface of the first lead frame, and attaching the preprocessed first switching die, second switching die, and logic control die to the top surface of the first lead frame;
continuing to arrange a conductive medium above the first switching die, the second switching die, and the logic control die, and attaching the second lead frame above the first switching die, the second switching die, and the logic control die;
a second step: performing wire bonding respectively between the logic control die and the first switching die, the second switching die, the third portion of the first lead frame, and the third portion of the second lead frame; and
a third step: molding and encapsulating the integrated power electronic component after completion of the wire bonding to form a first molded body; arranging at least two wiring layers on a surface of the first molded body to alternately lead an input positive terminal and an input negative terminal out to the surface of the first molded body; mounting a capacitor and other passive components on the surface of the first molded body, and molding the capacitor and the other passive components through secondary molding to form a second molded body;
removing redundant structures at a periphery of the lead frames and non-functional portions of tie bars of the lead frames, and forming, by a plating process, a signal pin, a first power pin, a second power pin, and an SW pin on a bottom surface of the first molded body.

17. The method according to claim 16, wherein the third step further comprises leading the second power pin and the SW pin inside the integrated power electronic component out to a top portion or a side surface of the integrated power electronic component to form a top heat dissipation portion and a side heat dissipation portion.

18. A method for manufacturing the integrated power electronic component according to claim 15, comprising:
a first step: mounting the integrated die and the other passive components on the first surface of the substrate, and mounting the capacitor on the second surface of the substrate;
a second step: performing a double-sided molding process on the semi-finished integrated power electronic component having components mounted on both sides in the first step, thereby forming a third molded body and a fourth molded body;
a third step: performing a plating process on bottom surfaces of the third molded body and the fourth molded body, and forming the first power pin, the second power pin, the SW pin, and the signal pin; forming the top heat dissipation portion by plating on top surfaces of the third molded body and the fourth molded body; and forming the side heat dissipation portion by plating on a side surface of the third molded body.

19. The method according to claim 17, wherein the top heat dissipation portion is thermally connected with metal layer in a substrate, and the side heat dissipation portion is thermally connected with a surface of an integrated die.

20. A power unit, comprising:
an inductor comprising a magnetic core and a main winding, wherein the magnetic core comprises four side surfaces and a top surface and a bottom surface opposite to each other; and
the integrated power electronic component according to claim 1;
wherein the inductor and the integrated power electronic component are horizontally arranged; pins on the bottom surface of the integrated power electronic component are electrically connected with the inductor through a circuit board; the integrated power electronic component and the inductor are arranged on a top surface of the circuit board; and a side surface of the integrated power electronic component opposite to the side heat dissipation portion is arranged adjacent to the inductor.

21. The power unit according to claim 20, wherein the number of the integrated power electronic components is two, the two integrated power electronic components are respectively arranged adjacent to two opposite sides of the inductor, the inductor comprises two main windings, and one end of each main winding is electrically connected with one integrated power electronic component.

22. The power unit according to claim 20, wherein the top surface of the inductor and the top surface of the integrated power electronic component are substantially coplanar.

23. The power unit according to claim 20, wherein the number of the integrated power electronic components is four, and the four integrated power electronic components are arranged adjacent to one side surface of the magnetic core and sequentially arranged along the side surface; the inductor comprises four main windings, one end of each main winding is electrically connected with a respective integrated power electronic component, and the four main windings are sequentially arranged along the same direction.

24. The power unit according to claim 20, wherein the number of the integrated power electronic components is four, and the four integrated power electronic components are respectively arranged adjacent to one side surface of the magnetic core; the inductor comprises four main windings, one end of each main winding is electrically connected with a respective integrated power electronic component, and two ends of each main winding are respectively located on two adjacent side surfaces of the magnetic core.

25. The power unit according to claim 24, wherein output capacitors are arranged on the circuit board, and the output capacitors are arranged adjacent to side surfaces of two adjacent integrated power electronic components and four corners of the magnetic core.

26. The power unit according to claim 24, wherein the four integrated power electronic components are arranged around a periphery of the inductor in an end-to-end manner.

27. The power unit according to claim 20, wherein the number of the integrated power electronic components is four, and the four integrated power electronic components are arranged in two groups respectively on two opposite side surfaces of the magnetic core; the inductor comprises four main windings, one end of each main winding is electrically connected with a respective integrated power electronic component, and the four main windings are sequentially arranged in the magnetic core along a same direction.

28. The power unit according to claim 20, wherein the inductor further comprises an auxiliary winding; the magnetic core comprises a magnetic core window, and the main winding and the auxiliary winding pass through the same magnetic core window; and the main winding and the auxiliary winding are arranged in parallel or are vertically stacked.

29. The power unit according to claim 20, wherein a groove is provided in the bottom surface of the magnetic core, and an output capacitor is arranged in the groove.

30. A power supply architecture, comprising a semiconductor chip and the power unit according to claim 20, wherein the power unit supplies power to the semiconductor chip.

31. The power supply architecture according to claim 30, wherein the power unit and the semiconductor chip are horizontally arranged and are both arranged on the top surface of the circuit board.

32. The power supply architecture according to claim 30, wherein the power supply architecture further comprises a system board, and the power unit arranged on the circuit board and the semiconductor chip are horizontally arranged and are both arranged on a top surface of the system board.

33. The power supply architecture according to claim 30, wherein the number of the power units is M*N, where M and N are both natural numbers greater than 1; the M*N power units are electrically connected in parallel; the semiconductor chip is arranged adjacent to a bottom surface of the circuit board; and the M*N power units are arranged adjacent to the top surface of the circuit board.

34. The power supply architecture according to claim 33, wherein the power supply architecture further comprises a system board, the semiconductor chip is arranged on a bottom surface of the system board, and the circuit board is arranged on a top surface of the system board.
